(19) United States
(12) Patent Application Publication
(10) Pub. No.: US 2026/0172472 A1
(43) Pub. Date: Jun. 18, 2026

(54) NETWORK-BASED ERASURE-CODED MEMORY RESERVE

(71) Applicant: International Business Machines Corporation, Armonk, NY (US)

(72) Inventors: Ryan Kinsey Sanders, Naperville, IL (US); PAI-LIEN HSIEH, Hoffman Estates, IL (US); Mark Duane Seaborn, Algonquin, IL (US)

(73) Assignee: International Business Machines Corporation, Armonk, NY (US)

(21) Appl. No.: 18/983,752

(22) Filed: Dec. 17, 2024

(51) Int. Cl. H04L 67/1097; H03M 13/15

(52) U.S. Cl. CPC H04L 67/1097; H03M 13/154

(57) ABSTRACT

A group of devices is configured to deliver a network service using common data. An embodiment configures a first device with a first memory as a first erasure-coded memory. The first erasure-coded memory participates in an erasure-coded memory reserve which includes a group of erasure-coded memories corresponding to the group of devices. A first slice of the common data is stored in the first erasure-coded memory. A request for a second slice from a second erasure-coded memory is transmitted to a second device. The common data is constructed at the first device using the first slice and the second slice without communicating with a common source of the common data. The common data includes more slices than the first slice and the second slice, and the first slice and the second slice are each erasure-coded such that the common data can be constructed without the more slices.

### BACKGROUND

The present invention relates generally to the field of network services and memory management in computing environments that include devices scattered throughout the network. More particularly, the present invention relates to a method, system, and computer program for network-based erasure-coded memory reserve.

There are networks of computing devices in which a variety of devices, such as computers, sensors, mobile devices, Internet of Things (IoT) devices, and many other types of devices with processors, memory, and computing abilities, are scattered across the network. Devices in such networks are typically spread across different locations but can still interact and work together through a network. Different devices and systems can communicate and work together, often using standard protocols.

Devices operating in this manner in a network are able to use mechanisms that allow devices to find and interact with available services and other devices in the network. Some networks also facilitate the exchange of data between devices, often through APIs or messaging protocols. Generally, a central system operates as a backend location for shared data that is used by a group of devices (common data). A device in the group (accessor device) accesses this common data from the central system, makes a local copy in the accessor device's local memory, and uses the local copy of the common data in the accessor device's operations.

### SUMMARY

The illustrative embodiments provide for network-based erasure-coded memory reserve. An embodiment includes configuring, at a first device from a plurality of devices, a first memory as a first erasure-coded memory in a plurality of erasure-coded memories, the plurality of devices configured to deliver a network service using common data, the first erasure-coded memory participating in an erasure-coded memory reserve, the erasure-coded memory reserve comprising the plurality of erasure-coded memories corresponding to the plurality of devices. The embodiment further includes storing, in the first erasure-coded memory, a first slice of the common data. The embodiment further includes transmitting from the first device to a second device in the plurality of devices, responsive to a request for the network service at the first device, a first request for a second slice of the common data, the second slice being stored in a second erasure-coded memory in the second device. The embodiment further includes constructing, at the first device, using the first slice and the second slice, and without communicating with a common source of the common data, the common data, wherein the common data comprises more slices than the first slice and the second slice, and wherein the first slice and the second slice are each erasure-coded such that the common data can be constructed without the more slices.

Other embodiments of this aspect include corresponding computer systems, apparatus, and computer programs recorded on one or more computer storage devices, each configured to perform the actions of the embodiment.

An embodiment includes a computer-usable program product. The computer-usable program product includes a computer-readable storage medium and program instructions stored on the storage medium.

An embodiment includes a computer system. The computer system includes a processor, a computer-readable memory, and a computer-readable storage medium, and program instructions stored on the storage medium for execution by the processor via the memory.

### BRIEF DESCRIPTION OF THE DRAWINGS

The novel features believed characteristic of the invention are set forth in the appended claims. The invention itself, however, as well as a preferred mode of use, further objectives, and advantages thereof, will best be understood by reference to the following detailed description of the illustrative embodiments when read in conjunction with the accompanying drawings, wherein:

FIG. 1 depicts a block diagram of a computing environment in accordance with an illustrative embodiment;

FIG. 2 depicts a block diagram of an example configuration for delivering network services, which can be improved in accordance with an illustrative embodiment;

FIG. 3 depicts a configuration for network-based erasure-coded memory reserve in accordance with an illustrative embodiment;

FIG. 4 depicts a configuration for network-based erasure-coded memory reserve in which erasure-coded error recovery occurs in accordance with an illustrative embodiment;

FIG. 5 depicts a flowchart of an example process for network-based erasure-coded memory reserve in accordance with an illustrative embodiment;

FIG. 6 depicts a flowchart of an example process for updating an erasure-coded memory reserve in accordance with an illustrative embodiment; and

FIG. 7 depicts a flowchart of an example process for recovering an erasure-coded memory reserve in accordance with an illustrative embodiment.

### DETAILED DESCRIPTION

The illustrative embodiments recognize that in presently deployed device networks, network services that rely on a multitude of devices needing access to the same data must typically read that data from a common source. That common data is typically stored at a central system acting as the common source. Each device that needs the common data communicates with the central system and makes a duplicate of the common data in the device's local memory.

As the number of devices needed to implement the service increases, duplication of this common data increases because each device needs a full copy of the data to run the service. The illustrative embodiments recognize that this method of operating network services over numerous devices increases the data network load, data storage demand, and the demand for computing resources at the common source of data.

The illustrative embodiments further recognize that the typical approach in the industry today is for all devices implementing such a network service to receive the common data from the common source and cache the common data fully and individually at each of the devices. Accordingly, the illustrative embodiments recognize that this manner of implementing network services using scattered also devices wastes precious memory capacity at the devices by maintaining full local copies of the common data in local memory; local memory is often a scarce resource at the devices. In addition, the illustrative embodiments recognize that each device must make the same request to read data from the common source to create this local copy of the common data. Such requests also increase the data network load and the demand for computing resources at the devices.

To help address these and similar problems with network services employing numerous scattered and networked devices, the illustrative embodiments provide a system and method for network-based erasure-coded memory reserve. The illustrative embodiments create a network-based erasure-coded memory reserve that enables all devices in a group to collaborate and keep each other up to date. Erasure coding is a data protection technique used to ensure reliability and fault tolerance in storage systems. Erasure coding involves breaking up data into smaller pieces or slices, encoding each slice with additional redundant information, and then distributing the slices across different storage locations or devices. For example, the original data and the redundant data for recovery may together be split into n slices. If a certain number of slices (up to a threshold—e.g., m slices out of n total slices) are lost or corrupted, the original data can still be reconstructed using the remaining slices. The redundancy in erasure coding allows for flexible recovery, ensuring data durability.

Thus, a network-based erasure-coded memory (which may be compactly referred to herein as “erasure-coded memory”) is a memory residing in a device, and the device is operating on a network to deliver a network service as described herein. The device as described herein may be an access device. The memory in the device is erasure-coded such that the memory stores a slice of the common data instead of the entire common data.

The network-based erasure-coded memory reserve is a collective reference to all the erasure-coded memories in all the devices configured in this manner in a participating group of devices. Thus, an erasure-coded memory reserve according to the illustrative embodiments is implemented, in part, in memory on each device participating in the storing mechanism and storing a slice of the common data.

The illustrative embodiments offer a solution to the problem described above by creating a network-based erasure-coded memory reserve that all participating devices collaborate on to keep up to date. This reserve is located on each device that participates in the storing mechanism in the form of a slice of the reserve. The entire reserve can be encoded; as the reserve size grows, common data may be segmented, and each segment may be erasure coded and distributed separately.

In one embodiment, the entire common data is erasure-coded as one piece of data and stored in an erasure-coded memory reserve in a group of devices. In another embodiment, the common data can be segmented into a plurality of segments, and one, all, or some segments can be selectively and separately erasure-coded and distributed to an erasure-coded memory reserve. For example, the common data may include three segments as depicted in the figures.

Each segment can be separately erasure-coded such that segment 1 has x slices, segment 2 has y slices, segment 3 has z slices, and so on. The x, y, and z slices are distributed among the devices in a group of devices. Different segments can, but need not necessarily, be erasure-coded into the same number of slices. Different segments of the common data can, but need not necessarily, be distributed to the same subgroups of devices. For example, slices of segment 1 may be distributed to the erasure-coded memory reserve formed using devices d1, d3, and d5, but slices of segments 2 and 3 may be distributed to the erasure-coded memory reserve formed using devices d1, d4, d5, and d6.

Over time, as the network service processes client requests, the common data can change. For example, one device that has one slice in the device's erasure-coded memory may perform a function that causes some portion of the common data (not necessarily the slice of the common data in that device) to change. In the presently available solutions, the new information is pushed from the device with the new information to the common data source, such as a common cache, for retrieval by other service delivery devices.

In contrast, an embodiment causes the erasure-coded memory reserve to be updated with the new information using a suitable method for updating one or more slices in the erasure-coded memory reserve. Updating a slice in the device's erasure-coded memory causes a transformation of that slice into an updated slice where the transformation refers to the change in the slice data in the device's erasure-coded memory caused by the update.

The updating of one or more slices in the erasure-coded memory reserve also advantageously limits the number of requests needed to propagate a change in the common data. Distributed rate limiting is a result of this manner of distributed management of common data because neither the common source nor the change-causing device is inundated with requests for data updates. No single device is subjected to too many requests for updates because the updated slice can be propagated in the group of participating devices by any device that has obtained the updated slice.

In one embodiment, the device that causes such an update also triggers an update of a copy of common data at a backend storage device as a backup. Such a backup is useful in case a failure occurs in the erasure-coded memory reserve such that the remaining non-failed slices in the erasure-coded memory reserve fall below the threshold and the current state of the common data has to be sliced and redistributed to the participating devices.

By using slices in the erasure-encoded memory erasure-encoded memory, the illustrative embodiments advantageously avoid data traffic from all participating devices to a common source for requesting updates and data traffic from the common source to all participating devices for delivering the entire common data separately. A participating device according to an embodiment communicates with another participating device to discover the slices available at the other device. As a result, the devices communicate among themselves without involving data communication with the common source and discover all the slices needed to construct the common data as needed at each device. When common data is updated, only certain slices are updated, and the updated slice is communicated back to the common source.

In one embodiment, participating devices can also collaborate in this manner to use their respective erasure-coded memories to store not only the common data slices but also slices of data that are local to one or more devices and shared or sharable by those one or more devices. For example, in the example described earlier where slices of segment 1 of the common data were distributed to the erasure-coded memory reserve formed using devices d1, d3, and d5, slices of segment 2 and 3 of the common data were distributed to the erasure-coded memory reserve formed using devices d1, d4, d5, and d6. According to this embodiment, devices d1, d3, and d5 could also share local data that was only in device d1 prior to the embodiment such that devices d1, d3, and d5 also store slices of that local data of d1 in their respective erasure-coded memories. Similarly, devices d1, d4, d5, and d6 could store in their respective erasure-coded memories the slices of local data of device d5 and local data of device d6. In this manner, the embodiment further reduces the memory load in the participating devices by the erasure-coded distribution of both the common data of a common source and the local data of one or more participating devices.

In one embodiment, a distributed lock mechanism can be implemented to ensure only the participating devices from the universe of devices are able to receive, understand, and/or use the slices of common data, slices of local data, or both. For example, where a subset of a set of devices shares slices of local data, a suitable encryption method can be employed to limit access to only the members of the subset. For example, the device whose local data is being sliced and distributed can encrypt using an encryption key. Only the members of the subset, who would be the only devices to have the decryption key, can decrypt the slices, thereby preventing nonmembers of the subset from accessing the local data. A segment of the common data can also be limited in distribution and accessed in a similar manner within the scope of the illustrative embodiments.

For the sake of clarity of the description, and without implying any limitation thereto, the illustrative embodiments are described using some example configurations. From this disclosure, those of ordinary skill in the art will be able to conceive many alterations, adaptations, and modifications of a described configuration for achieving a described purpose, and the same are contemplated within the scope of the illustrative embodiments.

Furthermore, simplified diagrams of the data processing environments are used in the figures and the illustrative embodiments. In an actual computing environment, additional structures or components that are not shown or described herein, or structures or components different from those shown but for a similar function as described herein, may be present without departing the scope of the illustrative embodiments.

Furthermore, the illustrative embodiments are described with respect to specific actual or hypothetical components only as examples. Any specific manifestations of these and other similar artifacts are not intended to be limiting. Any suitable manifestation of these and other similar artifacts can be selected within the scope of the illustrative embodiments.

The examples in this disclosure are used only for the clarity of the description and are not limiting on the illustrative embodiments. Any advantages listed herein are only examples and are not intended to limit the illustrative embodiments. Additional or different advantages may be realized by specific illustrative embodiments. Furthermore, a particular illustrative embodiment may have some, all, or none of the advantages listed above.

Furthermore, the illustrative embodiments may be implemented with respect to any type of data, data source, or access to a data source over a data network. Any type of data storage device may provide the data to an embodiment of the invention, either locally at a data processing system or over a data network within the scope of the invention. Where an embodiment is described using a mobile device, any type of data storage device suitable for use with the mobile device may provide the data to such embodiment, either locally at the mobile device or over a data network, within the scope of the illustrative embodiments.

The illustrative embodiments are described using specific code, computer readable storage media, high-level features, designs, architectures, protocols, layouts, schematics, and tools only as examples and are not limiting to the illustrative embodiments. Furthermore, the illustrative embodiments are described in some instances using particular software, tools, and data processing environments only as an example for the clarity of the description. The illustrative embodiments may be used in conjunction with other comparable or similarly purposed structures, systems, applications, or architectures. For example, other comparable mobile devices, structures, systems, applications, or architectures therefor, may be used in conjunction with such embodiment of the invention within the scope of the invention. An illustrative embodiment may be implemented in hardware, software, or a combination thereof.

The examples in this disclosure are used only for the clarity of the description and do not limit the illustrative embodiments. Additional data, operations, actions, tasks, activities, and manipulations will be conceivable from this disclosure and the same are contemplated within the scope of the illustrative embodiments.

Various aspects of the present disclosure are described by narrative text, flowcharts, block diagrams of computer systems, and/or block diagrams of the machine logic included in computer program product (CPP) embodiments. With respect to any flowcharts, depending upon the technology involved, the operations can be performed in a different order than what is shown in a given flowchart. For example, again, depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

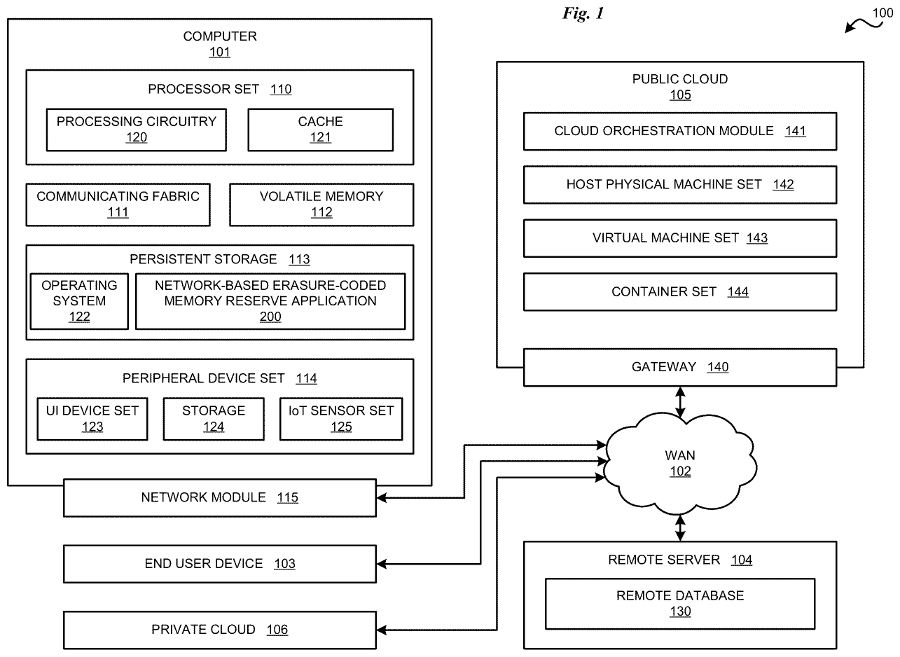

With reference to FIG. 1, this figure depicts a block diagram of a computing environment 100. Computing environment 100 contains an example of an environment for the execution of at least some of the computer code involved in performing the inventive methods, such as network-based erasure-coded memory reserve application 200 that may execute in computer 101 (which may be a manifestation of an accessor device/participating device/device with an erasure-coded memory/device participating in an erasure-coded memory reserve as described herein) in a network service delivery environment 100 and implement one or more embodiments for network-based erasure-coded memory reserve as described herein. In addition to the network-based erasure-coded memory reserve application 200, computing environment 100 includes, for example, computer 101, wide area network (WAN) 102, end user device (EUD) 103, remote server 104, public cloud 105, and private cloud 106. In this embodiment, computer 101 includes processor set 110 (including processing circuitry 120 and cache 121), communication fabric 111, volatile memory 112, persistent storage 113 (including operating system 122 and the network-based erasure-coded memory reserve application 200, as identified above), peripheral device set 114 (including user interface (UI) device set 123, storage 124, and Internet of Things (IoT) sensor set 125), and network module 115. Remote server 104 includes remote database 130. Public cloud 105 includes gateway 140, cloud orchestration module 141, host physical machine set 142, virtual machine set 143, and container set 144.

COMPUTER 101 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 130. As is well understood in the art of computer technology, and depending upon the technology, performance of a computer-implemented method may be distributed among multiple computers and/or between multiple locations. On the other hand, in this presentation of computing environment 100, detailed discussion is focused on a single computer, specifically computer 101, to keep the presentation as simple as possible. Computer 101 may be located in a cloud, even though it is not shown in a cloud in FIG. 1. On the other hand, computer 101 is not required to be in a cloud except to any extent as may be affirmatively indicated.

PROCESSOR SET 110 includes one, or more, computer processors of any type now known or to be developed in the future. Processing circuitry 120 may be distributed over multiple packages, for example, multiple, coordinated integrated circuit chips. Processing circuitry 120 may implement multiple processor threads and/or multiple processor cores. Cache 121 is memory that is located in the processor chip package(s) and is typically used for data or code that should be available for rapid access by the threads or cores running on processor set 110. Cache memories are typically organized into multiple levels depending upon relative proximity to the processing circuitry. Alternatively, some, or all, of the cache for the processor set may be located “off chip.” In some computing environments, processor set 110 may be designed for working with qubits and performing quantum computing.

Computer readable program instructions are typically loaded onto computer 101 to cause a series of operational steps to be performed by processor set 110 of computer 101 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 121 and the other storage media discussed below. The program instructions, and associated data, are accessed by processor set 110 to control and direct performance of the inventive methods. In computing environment 100, at least some of the instructions for performing the inventive methods may be stored in the network-based erasure-coded memory reserve application 200 in persistent storage 113.

COMMUNICATION FABRIC 111 is the signal conduction path that allows the various components of computer 101 to communicate with each other. Typically, this fabric is made of switches and electrically conductive paths, such as the switches and electrically conductive paths that make up buses, bridges, physical input/output ports and the like. Other types of signal communication paths may be used, such as fiber optic communication paths and/or wireless communication paths.

VOLATILE MEMORY 112 is any type of volatile memory now known or to be developed in the future. Examples include dynamic type random access memory (RAM) or static type RAM. Typically, volatile memory 112 is characterized by random access, but this is not required unless affirmatively indicated. In computer 101, the volatile memory 112 is located in a single package and is internal to computer 101, but, alternatively or additionally, the volatile memory may be distributed over multiple packages and/or located externally with respect to computer 101.

PERSISTENT STORAGE 113 is any form of non-volatile storage for computers that is now known or to be developed in the future. The non-volatility of this storage means that the stored data is maintained regardless of whether power is being supplied to computer 101 and/or directly to persistent storage 113. Persistent storage 113 may be a read only memory (ROM), but typically at least a portion of the persistent storage allows writing of data, deletion of data and re-writing of data. Some familiar forms of persistent storage include magnetic disks and solid state storage devices. Operating system 122 may take several forms, such as various known proprietary operating systems or open source Portable Operating System Interface-type operating systems that employ a kernel. The code included in the network-based erasure-coded memory reserve application 200 typically includes at least some of the computer code involved in performing the inventive methods.

PERIPHERAL DEVICE SET 114 includes the set of peripheral devices of computer 101. Data communication connections between the peripheral devices and the other components of computer 101 may be implemented in various ways, such as Bluetooth connections, Near-Field Communication (NFC) connections, connections made by cables (such as universal serial bus (USB) type cables), insertion-type connections (for example, secure digital (SD) card), connections made through local area communication networks and even connections made through wide area networks such as the internet. In various embodiments, UI device set 123 may include components such as a display screen, speaker, microphone, wearable devices (such as goggles and smart watches), keyboard, mouse, printer, touchpad, game controllers, and haptic devices. Storage 124 is external storage, such as an external hard drive, or insertable storage, such as an SD card. Storage 124 may be persistent and/or volatile. In some embodiments, storage 124 may take the form of a quantum computing storage device for storing data in the form of qubits. In embodiments where computer 101 is required to have a large amount of storage (for example, where computer 101 locally stores and manages a large database) then this storage may be provided by peripheral storage devices designed for storing very large amounts of data, such as a storage area network (SAN) that is shared by multiple, geographically distributed computers. IoT sensor set 125 is made up of sensors that can be used in Internet of Things applications. For example, one sensor may be a thermometer and another sensor may be a motion detector.

NETWORK MODULE 115 is the collection of computer software, hardware, and firmware that allows computer 101 to communicate with other computers through WAN 102. Network module 115 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 115 are performed on the same physical hardware device. In other embodiments (for example, embodiments that utilize software-defined networking (SDN)), the control functions and the forwarding functions of network module 115 are performed on physically separate devices, such that the control functions manage several different network hardware devices. Computer readable program instructions for performing the inventive methods can typically be downloaded to computer 101 from an external computer or external storage device through a network adapter card or network interface included in network module 115.

WAN 102 is any wide area network (for example, the internet) capable of communicating computer data over non-local distances by any technology for communicating computer data, now known or to be developed in the future. In some embodiments, the WAN 012 may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

END USER DEVICE (EUD) 103 is any computer system that is used and controlled by an end user (for example, a customer of an enterprise that operates computer 101), and may take any of the forms discussed above in connection with computer 101. EUD 103 typically receives helpful and useful data from the operations of computer 101. For example, in a hypothetical case where computer 101 is designed to provide a recommendation to an end user, this recommendation would typically be communicated from network module 115 of computer 101 through WAN 102 to EUD 103. In this way, EUD 103 can display, or otherwise present, the recommendation to an end user. In some embodiments, EUD 103 may be a client device, such as thin client, heavy client, mainframe computer, desktop computer and so on.

REMOTE SERVER 104 is any computer system that serves at least some data and/or functionality to computer 101. Remote server 104 may be controlled and used by the same entity that operates computer 101. Remote server 104 represents the machine(s) that collect and store helpful and useful data for use by other computers, such as computer 101. For example, in a hypothetical case where computer 101 is designed and programmed to provide a recommendation based on historical data, then this historical data may be provided to computer 101 from remote database 130 of remote server 104.

PUBLIC CLOUD 105 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 105 is performed by the computer hardware and/or software of cloud orchestration module 141. The computing resources provided by public cloud 105 are typically implemented by virtual computing environments that run on various computers making up the computers of host physical machine set 142, which is the universe of physical computers in and/or available to public cloud 105. The virtual computing environments (VCEs) typically take the form of virtual machines from virtual machine set 143 and/or containers from container set 144. It is understood that these VCEs may be stored as images and may be transferred among and between the various physical machine hosts, either as images or after instantiation of the VCE. Cloud orchestration module 141 manages the transfer and storage of images, deploys new instantiations of VCEs and manages active instantiations of VCE deployments. Gateway 140 is the collection of computer software, hardware, and firmware that allows public cloud 105 to communicate through WAN 102.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

PRIVATE CLOUD 106 is similar to public cloud 105, except that the computing resources are only available for use by a single enterprise. While private cloud 106 is depicted as being in communication with WAN 102, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 105 and private cloud 106 are both part of a larger hybrid cloud.

Measured service: cloud systems automatically control and optimize resource use by leveraging a metering capability at some level of abstraction appropriate to the type of service (e.g., storage, processing, bandwidth, and active user accounts). Resource usage can be monitored, controlled, reported, and invoiced, providing transparency for both the provider and consumer of the utilized service.

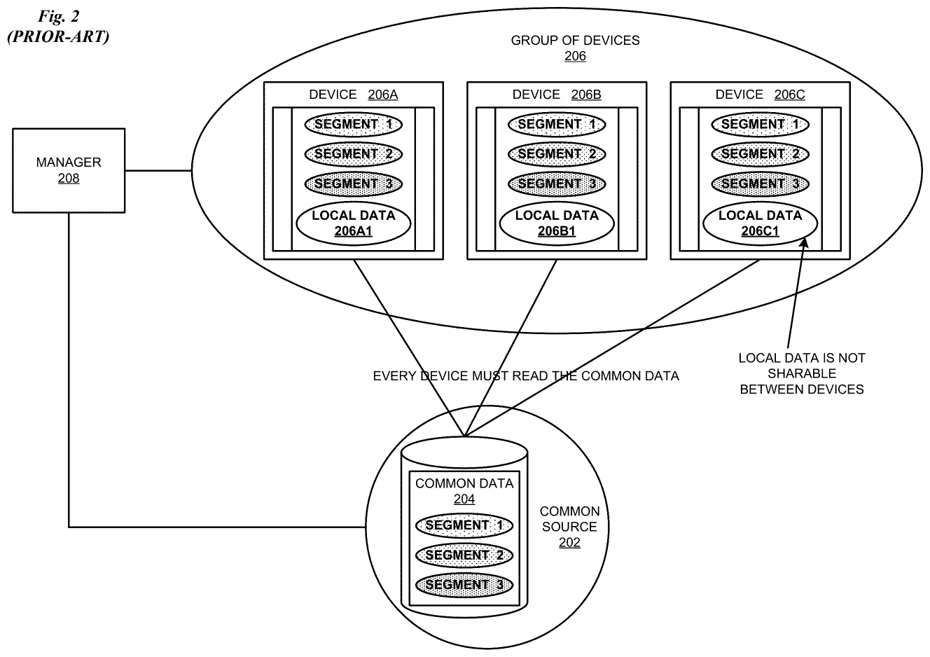

With reference to FIG. 2, this figure depicts a block diagram of an example configuration for delivering network services which can be improved in accordance with an illustrative embodiment. In a presently used configuration depicted in this figure, common source 202 shares common data 204 with group 206 of devices. The group 206 of devices includes devices 206A, 206B, and 206C. Manager 208 is an example management application that manages the operation of common source 202, the group 206 of devices, and the provision of the network service from the depicted configuration.

In an embodiment, the common data 204 includes segments of data, e.g., segments 1, 2, and 3. Common data 204 is needed by devices 206A-C for providing the network service. To provide the network service, each of devices 206A-C must presently request and receive the entirety of common data 204, including all of segments 1, 2, and 3. Furthermore, device 206A may contain local data 206A1, device 206B may contain local data 206B1, and device 206C may contain local data 206C1. Each device must store its own local data locally. Even if local data 206A1, 206B1, and 206C1 were to be identical, devices 206A-C save full copies of the local data individually. As can be seen, this arrangement disadvantageously requires excessive data communication load on the network, the common source, and the devices, computational resources at the common source and the devices, local memory at devices, and storage space at the common source.

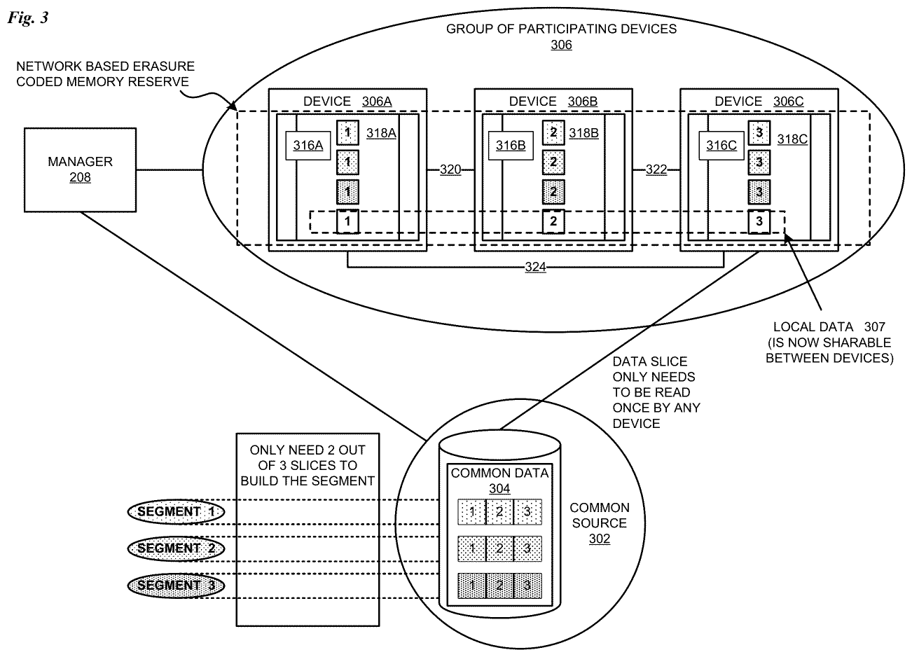

FIG. 3 depicts a configuration for network-based erasure-coded memory reserve in accordance with an illustrative embodiment. Manager 208 of FIG. 2 continues to manage the network service delivery. Common source 302 now stores common data 304 in a sliced manner that is erasure-coded, as described herein. The number of segments and slices depicted herein are chosen only for the clarity of the depiction and the description and are not intended to imply any limitation on the illustrative embodiments. Any number of data segments, each being sliceable into any number of slices for erasure coding, can similarly be implemented without departing the scope of the illustrative embodiments.

For example, segment 1 of common data 304 is sliced into three example slices (e.g., slices 1, 2, and 3, as shown), and only two of the three slices are needed to reconstruct segment 1 in case of an error or failure. Similarly, segment 2 of common data 304 is sliced into three example slices (e.g., 1, 2, and 3, as shown), and only two of the three slices are necessary to reconstruct segment 2 in case of an error or failure. Similarly, segment 3 of common data 304 is sliced into three example slices (e.g., 1, 2, and 3, as shown), and only two of the three slices are required to reconstruct segment 3 in case of an error or failure.

Now, in group 306 of participating devices, each participating device 306A, 306B, and 306C includes an application 316A, 316B, and 316C, respectively. Applications 316A-C are examples of the network-based erasure-coded memory reserve application 200 in FIG. 1. Each of applications 316A-C enables the corresponding device 306A-C, respectively, to create, populate, share, manage, and update a portion of the memory therein as erasure-coded memory member of an erasure-coded memory reserve, as described herein. For example, application 316A configures memory 318A within device 306A to participate as an erasure-coded memory in an erasure-coded memory reserve. Application 316A requests and receives only those one or more slices of one or more erasure-coded segments that would enable device 306A to participate in group 306 as an erasure-coded memory device. For example, application 316A obtains slice 1 of segment 1, slice 1 of segment 2, and slice 1 of segment 3 from common source 302 and stores each slice in erasure-coded memory 318A.

In a similar manner, application 316B configures memory 318B within device 306B to participate as an erasure-coded memory in an erasure-coded memory reserve. Application 316B requests and receives only those one or more slices of one or more erasure-coded segments that would enable device 306B to participate in group 306 as an erasure-coded memory device. For example, application 316B obtains slice 2 of segment 1, slice 2 of segment 2, and slice 2 of segment 3 from common source 302 and stores each slice in erasure-coded memory 318B. Application 316C configures memory 318C within device 306C to participate as an erasure-coded memory in an erasure-coded memory reserve. Application 316C requests and receives only those one or more slices of one or more erasure-coded segments that would enable device 306C to participate in group 306 as an erasure-coded memory device. For example, application 316C obtains slice 3 of segment 1, slice 3 of segment 2, and slice 3 of segment 3 from common source 302 and stores each slice in erasure-coded memory 318C.

Furthermore, applications 316A-C enable intragroup communication 320, 322, and 324 among devices 316A-C in group 306. Configured in this manner, using communication 320, 322, and 324, any of the devices 306A-C can construct any of segments 1, 2, or 3 of common data 304, as needed, without needing to communicate with common source 302.

This inter-device communication is also useful in slicing and distributing local data 307 in an erasure-coded manner. In an example, each of devices 306A-C has some local data 307 that is identical in each device. Applications 316A, 316B, and 316C also slice, or enable slicing of, local data 307. In this example, the distribution of the slices amongst the devices participating in the erasure-coded memory reserve also includes the distribution of slices of local data 307. For example, local data 307 is sliced by application 316C, slice 1 of local data 307 is sent to device 306A via a data communication 324 between application 316A and 316C, and slice 2 of local data 307 is sent to device 306B via a data communication 322 between application 316B and 316C. Slice 3 is kept at device 306C by application 316C.

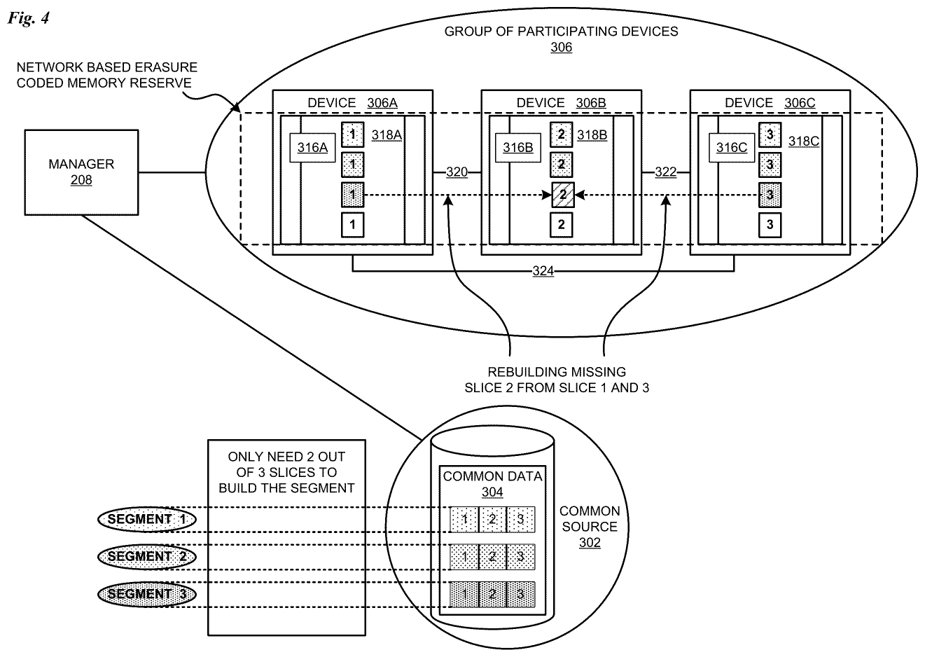

FIG. 4 depicts a configuration for network-based erasure-coded memory reserve in which erasure-coded error recovery occurs in accordance with an illustrative embodiment. Manager 208 of FIG. 2 continues to manage the network service delivery.

Continuing from the configuration of FIG. 3, in some embodiments, during the network operation, erasure-coded memory 318B in device 306B has slice 2 of segment 2, and slice 2 of segment 2 is corrupted or missing (e.g., when a slice cannot be found due to an error in storing or loading of the slice). Configured in the manner shown, application 316B uses communication 320 and 322 to reconstruct slice 2 of segment 2 of common data 304 at device 306B without needing to communicate with common source 302.

Using the configuration and operations described with respect to FIGS. 3-4, an actual implementation according to an embodiment may proceed as follows.

A common source, such as common source 302, may include one or more devices. A management unit, such as manager 208, may form a pool of such devices to form a “storage pool.” The information about the membership of the storage pool may be stored in a non-volatile memory associated with each dispersed storage processing unit in the storage pool.

The management unit may define a group of participating devices, such as group 306 of devices 306A-C, as an “access group.” A participating device can be regarded as a dispersed storage processing unit. Any number of dispersed storage processing units may be deployed in a given network. Volatile memory, which may also be referred to as a dispersed storage unit, may be added and configured in each dispersed storage processing unit for use as erasure-coded memory.

The management unit may define an error coding function for the storage pool and may operate the dispersed storage units in the dispersed storage processing units as a network-based erasure-coded memory reserve. To enable service in such a network configuration, a dispersed storage processing unit of the storage pool may begin by referencing the unit's own internal storage structures. The dispersed storage processing unit then reaches across the network to read from the non-volatile memory devices that make up the storage pool. Thereafter, the internal storage structure of the dispersed storage processing unit may be erasure-coded and stored in a network-based memory reserve. Other dispersed storage processing units may also read the internal data structure from the memory reserve in a similar manner.

During service delivery operations in the network, a dispersed storage processing unit may crash, restart, reboot, or be upgraded. When such an event occurs at a dispersed storage processing unit, a rebuilder module bound to the dispersed storage processing unit, such as by being a part of each of applications 316A-C, rebuilds the missing slices of error coding function encoded internal storage structures within the memory reserve. The time to keep the cache built up via the rebuilder module may be much faster compared to mechanisms where an entire cache of common data is maintained per dispersed storage processing unit.

Multiple dispersed storage processing units can simultaneously fail during operations. During a simultaneous restart, crash, reboot, or upgrade of multiple dispersed storage processing units, the configuration according to the illustrative embodiments enable service restoration by a single dispersed storage processing unit needing to read the internal storage structures from the storage pool and cache the common data in the memory reserve of the access pool. Other dispersed storage processing units may then read the common data from the memory reserve.

Within the scope of the illustrative embodiment, the management unit adjusts the error coding function of the access pool such that an aggregate amount of used volatile memory at any dispersed storage processing unit is less than the amount of volatile memory that would be required if each dispersed storage processing unit were to store an entire copy of the common data. The management unit further adjusts the error coding function such that the number of dispersed storage processing units required to read/write internal data structures of the memory reserve is a number less than all participating devices so the performance in delivering the requested service has a negligible or tolerable performance impact due to the use of the memory reserve.

In one embodiment, the management unit can be configured to have access to a number of dispersed storage processing units and network metrics to enforce a geographical policy for efficiency. For example, the management unit may apply a policy where the group of volatile memory devices, which make up the network-based erasure-coded memory reserve within the access pool, contain only those volatile memory devices that are situated within a defined geographic boundary.

This example implementation is not intended to be limiting. From this disclosure, those of ordinary skill in the art will be able to conceive many other ways of constructing and operating a network-based erasure-coded memory reserve across multiple dispersed storage processing units, and the same are contemplated within the scope of the illustrative embodiments.

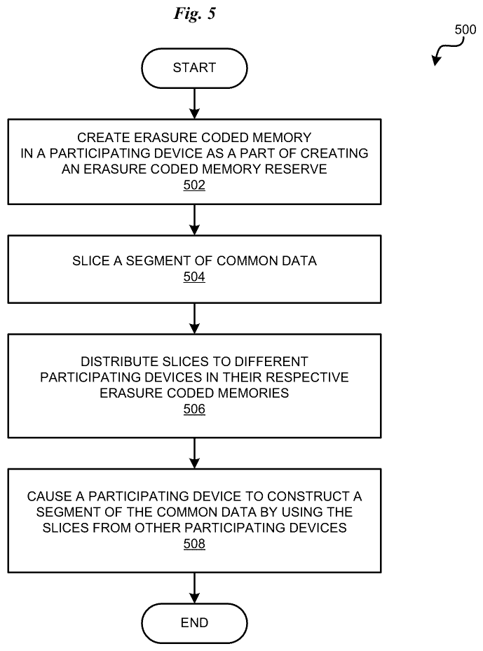

FIG. 5 depicts a flowchart of an example process for network-based erasure-coded memory reserve in accordance with an illustrative embodiment. Process 500 can be implemented in the network-based erasure-coded memory reserve application 200 of FIG. 1, such as in application 316A in device 306A, or application 316B in device 306B, or application 316C in device 306C in FIG. 3 or FIG. 4.

The process creates an erasure-coded memory in a participating device as a part of creating an erasure-coded memory reserve at block 502. The process slices a segment of common data at block 504. In one embodiment, the segment of common data is already sliced for erasure coding and the process at block 504 causes a slice to be requested from the common source.

The process distributes the slices to different devices for storing in the devices'respective erasure-coded memories at block 506. In one embodiment, the process causes a received slice to be stored in the device's erasure-coded memory. Once the slices are available at the participating devices in this manner, the process causes a participating device to construct a segment of the common data from the slice of the segment that is stored in the device and the slices of the segment stored in other participating devices at block 508. The process ends thereafter.

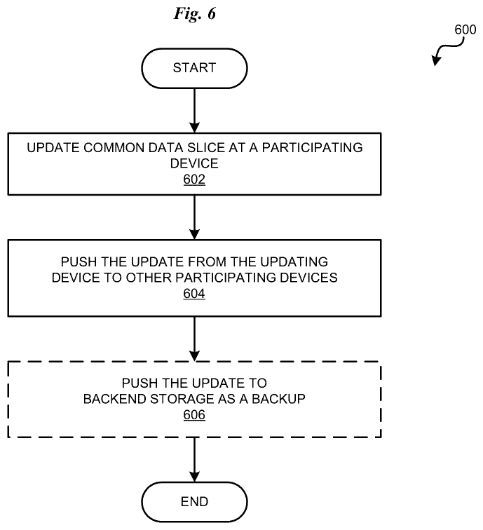

FIG. 6 depicts a flowchart of an example process for updating an erasure-coded memory reserve in accordance with an illustrative embodiment. Process 600 can be implemented in the network-based erasure-coded memory reserve application 200 of FIG. 1, such as in application 316A in device 306A, application 316B in device 306B, or application 316C in device 306C in FIG. 3 or FIG. 4.

The process updates a slice of the common data at a participating device at block 602. The process pushes the update from the updating device to one or more other devices that hold other slices of the segment of the common data that was updated by the updating device at block 604. The process optionally also pushes the update to a backend storage as a backup in case more than the threshold number of slices become unreliable or unreadable and the common data has to be reconstructed and redistributed in an erasure-coded manner described herein at block 606. The process ends thereafter.

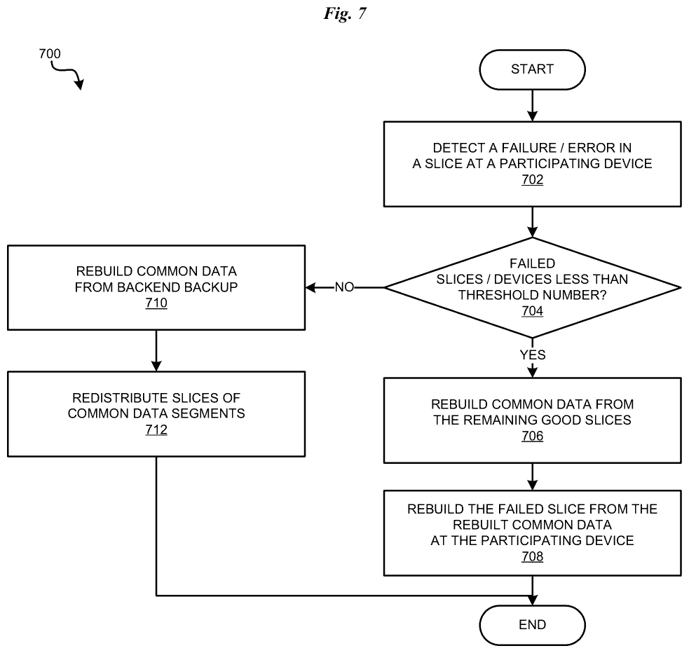

FIG. 7 depicts a flowchart of an example process for recovering an erasure-coded memory reserve in accordance with an illustrative embodiment. Process 700 can be implemented in the network-based erasure-coded memory reserve application 200 of FIG. 1, such as in application 316A in device 306A, application 316B in device 306B, or application 316C in device 306C in FIG. 3 or FIG. 4.

The process detects a failure or an error in a slice at a participating device at block 702. The process determines whether the total number of failed slices across all participating devices is less than the threshold number at block 704. If the total number of failed slices across all participating devices is less than the threshold number (the “Yes” path of block 704), the process rebuilds the common data (or a segment thereof) from the remaining non-failed slices in the group of participating devices at block 706. Optionally, the process rebuilds the failed slice from the rebuilt common data at the participating device at block 708. The process ends thereafter.

If the total number of failed slices across all participating devices is equal to or greater than the threshold number (the “No” path of block 704), the process causes a rebuilding of the common data from a backend backup at block 710. The process then causes a re-slicing and redistribution of the rebuilt common data at block 712. The process ends thereafter.

The following definitions and abbreviations are to be used for the interpretation of the claims and the specification. As used herein, the terms “comprises,” “comprising,” “includes,” “including,” “has,” “having,” “contains,” or “containing,” or any other variation thereof are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “illustrative” is used herein to mean “serving as an example, instance or illustration.” Any embodiment or design described herein as “illustrative” is not necessarily to be construed as preferred or advantageous over other embodiments or designs. The terms “at least one” and “one or more” are understood to include any integer number greater than or equal to one, e.g., one, two, three, four, etc. The terms “a plurality” are understood to include any integer number greater than or equal to two, e.g., two, three, four, five, etc. The term “connection” can include an indirect “connection” and a direct “connection.”

References in the specification to “one embodiment,” “an embodiment,” “an example embodiment,” etc. indicate that the embodiment described can include a particular feature, structure, or characteristic but that not every embodiment may include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

The terms “about,” “substantially,” “approximately,” and variations thereof are intended to include the degree of error associated with measurement of the particular quantity based upon the equipment available at the time of filing the application. For example, “about” can include a range of ±8%, 5%, or 2% of a given value.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, and/or to enable others of ordinary skill in the art to understand the embodiments described herein.

Thus, the present disclosure provides a computer implemented method, system, and computer program product in the illustrative embodiments for network-based erasure-coded memory reserves and other related features, functions, or operations. Where an embodiment or a portion thereof is described with respect to a type of device, the computer implemented method, system, computer program product, or a portion thereof are adapted or configured for use with a suitable and comparable manifestation of that type of device.

Where an embodiment is described as implemented in an application, the delivery of the application in a Software as a Service (SaaS) model is contemplated within the scope of the illustrative embodiments. In a SaaS model, the capability of the application implementing an embodiment is provided to a user by executing the application in a cloud infrastructure. The user can access the application using a variety of client devices through a thin client interface such as a web browser (e.g., web-based e-mail), or other light-weight client-applications. The user does not manage or control the underlying cloud infrastructure including the network, servers, operating systems, or the storage of the cloud infrastructure. In some cases, the user may not even manage or control the capabilities of the SaaS application. In some other cases, the SaaS implementation of the application may permit a possible exception of limited user-specific application configuration settings.

Embodiments of the present invention may also be delivered as part of a service engagement with a client corporation, nonprofit organization, government entity, internal organizational structure, or the like. Aspects of these embodiments may include configuring a computer system to perform, and deploying software, hardware, and web services that implement, some or all of the methods described herein. Aspects of these embodiments may also include analyzing the client's operations, creating recommendations responsive to the analysis, building systems that implement portions of the recommendations, integrating the systems into existing processes and infrastructure, metering use of the systems, allocating expenses to users of the systems, and billing for use of the systems. Although the above embodiments of present invention each have been described by stating their individual advantages, respectively, present invention is not limited to a particular combination thereof. To the contrary, such embodiments may also be combined in any way and number according to the intended deployment of present invention without losing their beneficial effects.

What is claimed is:

1. A computer-implemented method comprising:
configuring a first memory as a first erasure-coded memory in a plurality of erasure-coded memories at a first device of a plurality of devices, the plurality of devices configured to deliver a network service using common data, the first erasure-coded memory participating in an erasure-coded memory reserve, the erasure-coded memory reserve comprising the plurality of erasure-coded memories corresponding to the plurality of devices;
storing, in the first erasure-coded memory, a first slice of the common data;
transmitting a first request for a second slice of the common data from the first device to a second device in the plurality of devices responsive to a request for the network service at the first device, wherein the second slice is stored in a second erasure-coded memory in the second device; and
constructing the common data at the first device using the first slice and the second slice without communicating with a common source of the common data, wherein the common data comprises more slices than the first slice and the second slice, and wherein the first slice and the second slice are each erasure-coded such that the common data can be constructed without the more slices.

2. The computer-implemented method of claim 1, further comprising:
transmitting a second request for a third slice of the common data from the first device to a third device in the plurality of devices, responsive to the request for the network service at the first device, wherein the third slice is stored in a third erasure-coded memory in the third device;
determining that the third slice has an error; and
assembling the common data by omitting the third slice as a part of the constructing at the first device.

3. The computer-implemented method of claim 2, wherein the error is at the third erasure-coded memory in the third device.

4. The computer-implemented method of claim 2, further comprising:
causing a reconstruction of a new third slice using the constructed common data; and
replacing the third slice at the third erasure-coded memory in the third device with the new third slice.

5. The computer-implemented method of claim 1, further comprising:
changing data in the first slice at the first erasure-coded memory as a part of delivery of the network service from the first device, wherein the changing causes a transformation of the first slice into a new first slice; and
propagating the new first slice to the second device in response to a request for the first slice from the second device.

6. The computer-implemented method of claim 5, further comprising:
propagating the new first slice to the common source.

7. The computer-implemented method of claim 1, further comprising:
receiving, responsive to the transmitting, the second slice from the second device.

8. The computer-implemented method of claim 1, further comprising:
causing slicing of the common data into a plurality of slices at the common source in communication with the plurality of devices, wherein the plurality of slices comprises the first slice and the second slice.

9. The computer-implemented method of claim 1, further comprising:
causing slicing of a first segment of the common data into a plurality of slices at the common source in communication with the plurality of devices, wherein the plurality of slices comprises the first slice and the second slice, wherein the first segment is a member of a plurality of segments, and wherein the common data comprises the plurality of segments.

10. The computer-implemented method of claim 1, wherein the common source is a data processing system that serves as a backend system in communication with the plurality of devices.

11. A computer program product comprising:
one or more computer readable storage media; and
program instructions stored on the one or more storage media and configured to perform operations comprising:
configuring a first memory as a first erasure-coded memory in a plurality of erasure-coded memories at a first device of a plurality of devices, the plurality of devices configured to deliver a network service using common data, the first erasure-coded memory participating in an erasure-coded memory reserve, the erasure-coded memory reserve comprising the plurality of erasure-coded memories corresponding to the plurality of devices;
storing, in the first erasure-coded memory, a first slice of the common data;
transmitting a first request for a second slice of the common data from the first device to a second device in the plurality of devices responsive to a request for the network service at the first device, wherein the second slice is stored in a second erasure-coded memory in the second device; and
constructing the common data at the first device using the first slice and the second slice without communicating with a common source of the common data, wherein the common data comprises more slices than the first slice and the second slice, and wherein the first slice and the second slice are each erasure-coded such that the common data can be constructed without the more slices.

12. The computer program product of claim 11, the operations further comprising:
transmitting a second request for a third slice of the common data from the first device to a third device in the plurality of devices, responsive to the request for the network service at the first device, wherein the third slice is stored in a third erasure-coded memory in the third device;
determining that the third slice has an error; and
assembling the common data by omitting the third slice as a part of the constructing at the first device.

13. The computer program product of claim 12, wherein the error is at the third erasure-coded memory in the third device.

14. The computer program product of claim 12, further comprising:
causing a reconstruction of a new third slice using the constructed common data; and
replacing the third slice at the third erasure-coded memory in the third device with the new third slice.

15. The computer program product of claim 11, further comprising:
changing data in the first slice at the first erasure-coded memory as a part of delivery of the network service from the first device, wherein the changing causes a transformation of the first slice into a new first slice; and
propagating the new first slice to the second device in response to a request for the first slice from the second device.

16. The computer program product of claim 15, further comprising:
propagating the new first slice to the common source.

17. The computer program product of claim 11, further comprising:
receiving, responsive to the transmitting, the second slice from the second device.

18. The computer program product of claim 11, wherein the stored program instructions are stored in a computer readable storage device in a data processing system, and wherein the stored program instructions are transferred over a network from a remote data processing system.

19. The computer program product of claim 11, wherein the stored program instructions are stored in a computer readable storage device in a server data processing system, and wherein the stored program instructions are downloaded in response to a request over a network to a remote data processing system for use in a computer readable storage device associated with the remote data processing system, further comprising:
program instructions to meter use of the program instructions associated with the request; and
program instructions to generate an invoice based on the metered use.

20. A computer system comprising a processor and one or more computer readable storage media, and program instructions collectively stored on the one or more computer readable storage media, the program instructions executable by the processor to cause the processor to perform operations comprising:
configuring a first memory as a first erasure-coded memory in a plurality of erasure-coded memories at a first device of a plurality of devices, the plurality of devices configured to deliver a network service using common data, the first erasure-coded memory participating in an erasure-coded memory reserve, the erasure-coded memory reserve comprising the plurality of erasure-coded memories corresponding to the plurality of devices;
storing, in the first erasure-coded memory, a first slice of the common data;
transmitting a first request for a second slice of the common data from the first device to a second device in the plurality of devices responsive to a request for the network service at the first device, wherein the second slice is stored in a second erasure-coded memory in the second device; and
constructing the common data at the first device using the first slice and the second slice without communicating with a common source of the common data, wherein the common data comprises more slices than the first slice and the second slice, and wherein the first slice and the second slice are each erasure-coded such that the common data can be constructed without the more slices.
